(19) United States
(12) Patent Application Publication
(10) Pub. No.: US 2026/0262540 A1
(43) Pub. Date: Sep. 3, 2026

(54) STACKED MEMORY ARCHITECTURES WITH HIGHER THERMAL DESIGN POWER

(71) Applicant: Intel Corporation, Santa Clara, CA (US)

(72) Inventors: Amirhossein Mostafavi, Phoenix, AZ (US); Krishna Vasanth Valavala, Chandler, AZ (US); Debendra Mallik, Chandler, AZ (US); Omkar G. Karhade, Chandler, AZ (US)

(73) Assignee: Intel Corporation, Santa Clara, CA (US)

(21) Appl. No.: 19/067,092

(22) Filed: Feb. 28, 2025

(51) Int. Cl. H01L 25/18; H01L 23/00; H01L 23/367; H01L 23/48; H01L 23/538; H10B 80/00; H10D 80/30

(52) U.S. Cl. CPC H10W 90/00; H10B 80/00; H10D 80/30; H10W 20/20; H10W 40/22; H10W 70/611; H10W 90/401; H10W 90/20; H10W 90/288; H10W 90/297; H10W 90/724; H10W 90/792

(57) ABSTRACT

Devices and systems with stacked memory, and methods of forming the same, are disclosed herein. In one example, a microelectronic assembly includes a logic die, a stack of memory dies above the logic die, and a passthrough die between the logic die and the stack of memory dies, where the logic die is conductively coupled to the stack of memory dies through the passthrough die.

### BACKGROUND

Compute architectures designed for artificial intelligence (AI) and other memory-intensive applications often use stacked memory technologies, such as high-bandwidth memory (HBM), to provide a large capacity of memory with high-bandwidth access. For example, an HBM chip typically includes multiple memory dies stacked vertically on top of a base die containing memory access logic, and the HBM chip is typically integrated next to an associated processor. In this manner, the stacking of memory dies increases the overall memory capacity, and the close placement near the processor enables high-bandwidth memory access. As more and more memory dies are stacked in an HBM chip to achieve higher memory capacity, however, various thermal challenges are introduced, including higher thermal resistance and reduced heat spreading, which leads to lower thermal design power (TDP).

### BRIEF DESCRIPTION OF THE DRAWINGS

FIG. 1 illustrates a stacked memory chip with a passthrough die.

FIG. 2 illustrates a stacked memory chip with a thicker passthrough die and iso-height memory dies.

FIG. 3 illustrates a stacked memory chip with memory dies that have non-uniform thickness based on power requirements.

FIG. 4 illustrates a graph of the thermal design power of stacked memory chips with and without a passthrough die.

FIG. 5 illustrates a system with a stacked memory chip in accordance with certain embodiments.

FIG. 6 illustrates a flowchart for forming a stacked memory chip in accordance with certain embodiments.

FIG. 7 illustrates a top view of a wafer and dies that may be included in a microelectronic assembly.

FIG. 8 illustrates a cross-sectional view of an integrated circuit device that may be included in a microelectronic assembly.

FIG. 9 illustrates a cross-sectional view of an integrated circuit device assembly that may include a microelectronic assembly.

FIG. 10 illustrates a block diagram of an example electrical device that may include a microelectronic assembly.

### DETAILED DESCRIPTION

Many modern computing applications, such as artificial intelligence (AI) applications, require a large capacity of memory with high-bandwidth access. In some cases, this may be achieved by stacking multiple memory dies vertically on top of a base die that contains logic circuitry for managing memory access (e.g., memory controller and interconnect circuitry). The resulting stacked memory chip can then be integrated in an integrated circuit (IC) package immediately next to an associated compute die, such as a central processing unit (CPU), graphics processing unit (GPU), field-programmable gate array (FPGA), accelerator, or other processing unit (XPU). In this manner, the vertical stacking of memory dies increases the overall memory capacity, while the close proximity of the memory stack to the compute die enables high-bandwidth memory access.

For effective thermal management, it is preferable for the thickness or height of the memory stack to match that of the compute die (e.g., 720 μm-755 μm in some cases), as that allows them to be simultaneously cooled using a unified cooling solution. Due to this constraint, however, if more memory dies are stacked together to increase memory capacity, the individual memory dies must be thinned to maintain the same requisite height. For example, if a stacked memory architecture with 8 memory dies increases to 12 memory dies, the memory dies in the 12-die stack—and potentially the base die—must be thinned to maintain the same overall height as the 8-die stack.

As a result, in the pursuit of higher memory capacity and bandwidth, many AI compute architectures are trending toward stacking larger numbers of increasingly-thin memory dies. Unfortunately, this trend introduces various thermal challenges in stacked memory, including higher thermal resistance and reduced heat spreading, which leads to lower thermal design power (TDP). For example, heat generated by high-power-density circuitry in the base die must travel through additional stacked memory dies to dissipate, which increases overall thermal resistance. Moreover, thinning the memory dies and the base die reduces heat spreading in the dies, as heat spreads less effectively in thinner die substrates (e.g., silicon substrates). The reduced heat spreading can be particularly problematic for the base die, which typically has high power density and generates significant heat. This problem is further exacerbated when the first (bottom) memory die on top of the base die also has high power density (e.g., due to a high frequency of read/write operations on that die), as significant heat is generated in the bottom two dies (e.g., the base die and the first memory die).

High-bandwidth memory (HBM) is currently the most widely-used stacked memory technology for AI compute architectures. Other forms of stacked memory with varying memory and interconnect technologies are also emerging in the industry. The challenges described above are common to all flavors of stacked memory.

Currently, no viable solution exists to fully mitigate these challenges. The only practical approach is enforcing power limitations to ensure memory temperatures remain within safe operational limits.

Accordingly, this disclosure presents embodiments of stacked memory chips that achieve higher thermal design power (TDP) using a passthrough die and/or using memory dies with non-uniform thickness.

In some embodiments, for example, a stacked memory chip may include a passthrough die positioned between the base logic die and the first (e.g., lowest) memory die in the stack of memory dies. The passthrough die may include a substrate with high thermal conductivity, such as a silicon substrate, along with passthrough connections (e.g., through-substrate vias (TSVs) and/or redistribution layers (RDLs)) to enable the base die and the first memory die to be electrically connected through the passthrough die. In this manner, the passthrough die provides better heat spreading for heat generated in the high-power base die and/or first memory die, which reduces thermal resistance and achieves higher TDP.

Alternatively, or additionally, a stacked memory chip may include memory dies with non-uniform thickness, where the thickness of the respective memory dies is based on their respective power requirements (e.g., such that the highest-power memory die is the thickest). In some embodiments, for example, the first (e.g., lowest) memory die in the stack may require more power than the other memory dies due to a higher frequency of read/write operations on that die. In those embodiments, since the first memory die has the highest power and generates the most heat, the first memory die may be thicker than the other memory dies to enhance heat spreading in that die. In various embodiments, the remaining (thinner) memory dies may have uniform thickness, or their thicknesses may similarly vary based on their respective power requirements.

The described embodiments may provide various advantages. For example, the described embodiments alleviate the thermal challenges in stacked memory by boosting heat spreading for the highest-power dies that generate the most heat (e.g., the base die and/or first memory die), which reduces thermal resistance, improves heat dissipation efficiency, and results in higher TDP. In this manner, the described embodiments enable higher cooling capability for stacked memory, which enhances speed and performance. Further, the described embodiments enable a larger number of memory dies to be included in stacked memory chips, thus increasing the overall memory capacity, which is particularly beneficial for AI and other memory-intensive applications.

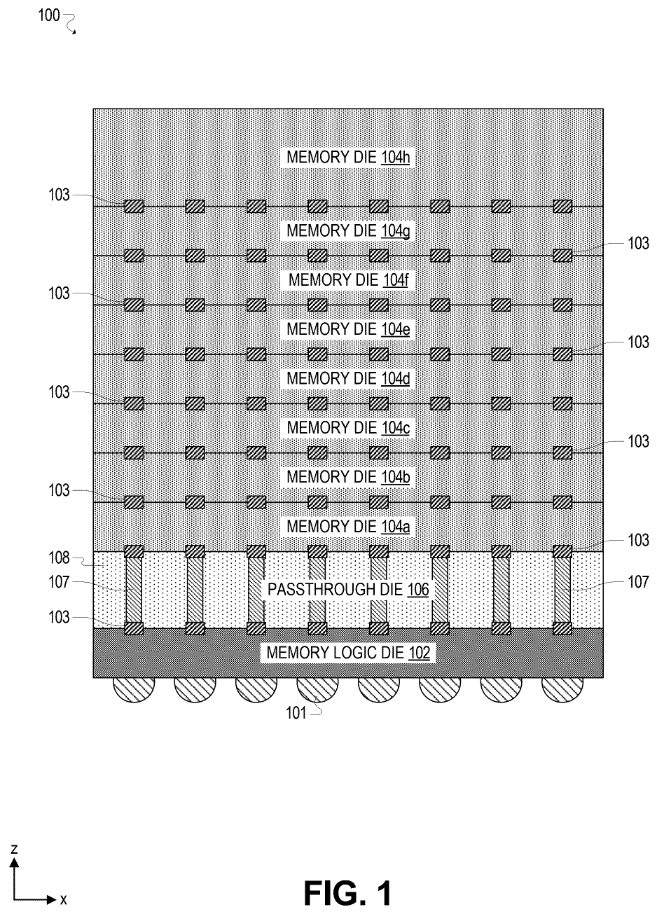

FIG. 1 illustrates a cross-section (x-z plane) view of a stacked memory chip 100 with a passthrough die 106. In the illustrated embodiment, stacked memory chip 100 includes a base memory logic die 102, a stack of eight memory dies 104a-h stacked vertically above the base logic die 102, and a passthrough die 106 positioned between the base logic die 102 and the first memory die 104a (e.g., the lowest or bottom memory die 104a) in the stack of memory dies 104a-h. The passthrough die 106 includes a passthrough substrate 108 with high thermal conductivity to enhance heat spreading, along with one or more passthrough electrical connections 107 through the substrate 108. In this manner, the thermally-conductive substrate 108 provides better heat spreading for heat generated in the base die 102 and the first memory die 104a, while the passthrough connections 107 enable the base logic die 102 to be conductively (e.g., electrically) coupled to the first memory die 104a (and in turn, to the other memory dies 104b-h in the stack) through the passthrough die 106.

In particular, the base logic die 102 and the first memory die 104a typically have high power density, as the base logic die 102 manages access to the memory dies 102a-h, and the first memory die 104a typically experiences a higher frequency of read/write operations than the other memory dies 104b-h. As a result, significant heat can be generated in the base logic die 102 and the first memory die 104a. This becomes even more problematic if the high-power-density circuitry in the base die 102 is facing up (e.g., rather than facing down), as the base die 102 and the first memory die 104a generate heat in even closer proximity to each other.

In the illustrated embodiment, however, the passthrough die 106 is positioned between the base die 102 and the first memory die 104a. In this manner, the passthrough die 106 may serve as a passive interposer or interconnect to connect the base die 102 to first memory die 104a, while also providing enhanced heat spreading for heat generated by those high-powered dies 102, 104a. As a result, the passthrough die 106 helps reduce thermal resistance and enables the stacked memory chip 100 to achieve higher thermal design power (TDP), thus mitigating the thermal challenges present in densely-stacked memory products.

The use of the passthrough die 106 also enables a higher density of through-silicon vias (TSVs) in the base die 102. In particular, while a similar thermal spreading effect could be achieved by designing the base die 102 with higher thickness, that would limit the ability to scale the TSV pitch/density in the base die 102, as scaling down the pitch of TSVs imposes constraints on the maximum thickness of the base die 102. However, by using a separate passthrough die 106 to mitigate the thermal challenges (e.g., instead of making the base die 102 thicker), the base die 102 can be thinned as needed to reduce TSV pitch and increase TSV density.

The thermally-conductive passthrough substrate 108 may be made of any material with high thermal conductivity, including, without limitation, silicon, diamond, diamond composite materials (e.g., a silver-diamond composite), hexagonal boron nitride (h-BN), aluminum nitride (AlN), or silicon carbide (SiC). Thus, in some embodiments, the passthrough substrate 108 may include elements such as silicon (Si), carbon (C), or boron (B) and nitrogen (N).

In the illustrated embodiment, the passthrough connections 107 include through-substrate vias (TSVs). A through-substrate via (TSV) may refer to a via that extends through the entire thickness of a substrate (e.g., between the frontside/backside), such as a through-silicon via (TSV) in a silicon substrate, a through-diamond via (TDV) in a diamond substrate, etc. In other embodiments, the passthrough connections 107 may include any type or combination of electrical connections, such as through-substrate vias (TSVs), layers of conductive traces and vias (e.g., redistribution layers (RDLs)), etc.

In some embodiments, the passthrough die 106 may include a silicon substrate 108 with one or more through-silicon vias (TSVs) 107. In some embodiments, the passthrough die 106 may be an interposer (e.g., with one or more conductive traces and vias), such as a passive interposer or an active interposer (e.g., with active logic circuity such as transistors).

In the illustrated embodiment, the passthrough die 106 is thicker than all of the respective memory dies 104a-g except for the top memory die 104h. In various embodiments, however, the passthrough die 106 may be thicker than some, all, or none of the respective memory dies 104a-h. In some embodiments, the passthrough die 106 may have a thickness ranging from about 1-50 microns (μm).

The passthrough die 106 may also be referred to as a passthrough carrier, a passthrough substrate, a passive or active passthrough die, a passive or active interposer, passthrough silicon, a passthrough silicon carrier, and variations thereof.

The memory dies 104a-h may respectively include a substrate with memory circuitry formed thereon (e.g., memory cells, interconnect layers, etc.). In some embodiments, the memory dies 104a-h may include random access memory (RAM), such as dynamic random access memory (DRAM)

In some embodiments, at least some of the memory dies 104a-h (e.g., all memory dies 104a-g except the top die 104h) may include one or more through-silicon vias (TSVs) (not shown) to enable the respective memory dies 104a-h in the stack to be conductively coupled to the base logic die 102 (e.g., through the passthrough die 106).

In the illustrated embodiment, the top memory die 102h is thicker than the other memory dies 102a-g in the stack. In particular, since no other memory dies are stacked on top of the top memory die 102h, no through-silicon vias (TSVs) are required in the top memory die 102h. As a result, the top memory die 102h is not subject to any design constraints on die thickness due to TSVs (e.g., thickness constraints due to TSV pitch density requirements). Thus, in the illustrated embodiment, the top memory die 102h is thicker, and thus has higher heat spreading efficiency, than the other memory dies 102a-g. In various embodiments, however, the top memory die 102h may have higher thickness, the same thickness, or lower thickness than some or all of the other memory dies 102a-g in the stack. In some embodiments, the respective memory dies 104a-h may have a thickness ranging from about 20-50 microns (μm).

The memory logic die 102 may include logic circuitry to manage memory access to the respective memory dies 104a-h. In some embodiments, for example, the memory logic die 102 may include a memory controller, interconnect logic, etc. The memory logic die 102 may also be referred to as a logic die, a base die, a base logic die, a base memory logic die, and variations thereof. In some embodiments, the base logic die 102 may contain memory logic and/or other types of logic (e.g., compute logic in a base compute die 102), and the power in the base logic die 102 may be local (e.g., distributed non-uniformly).

In the illustrated embodiment, the respective dies 102, 104a-h, 106 in stacked memory chip 100 are attached and conductively coupled to each other via hybrid bond interconnects (HBIs) 103. In particular, an HBI interconnect 103 (which may also be referred to as a direct bond interconnect (DBI)) may include hybrid dielectric-to-dielectric and metal-to-metal bonds formed at the interface between two dies, thus conductively coupling the dies to each other.

In the illustrated embodiment, for example, the base memory logic die 102 is attached and conductively coupled to the passthrough die 106 via an HBI interconnect 103, the passthrough die 106 is attached and conductively coupled to the first (e.g., lowest or bottom) memory die 104a in the stack via an HBI interconnect 103, and adjacent memory dies 104a-h in the stack are attached and conductively coupled to each other via respective HBI interconnects 103.

Moreover, the base memory logic die 102 includes a bump interconnect 101 (e.g., ball grid array (BGA) or micro BGA (μBGA) interconnect) on the bottom side, which enables the stacked memory chip 100 to be attached and conductively coupled to another integrated circuit (IC) component (not shown), such as an interposer, an IC package substrate, or a printed circuit board (PCB).

In various embodiments, however, the respective dies 102, 104a-h, 106 may be attached and conductively coupled to each other and/or to other components using any suitable interconnect technologies, including, without limitation, HBI interconnects and/or bump interconnects (e.g., BGA, micro-BGA (μBGA)).

In the illustrated embodiment, stacked memory chip 100 includes a stack of eight memory dies 104 a-h, which means stacked memory chip 100 has a stack height of 8 H. In other embodiments, however, stacked memory chip 100 may include any number of memory dies 104 with any stack height (e.g., 12 memory dies (12 H), sixteen memory dies (16 H), etc.).

In some embodiments, the base die 102 may have a larger size (e.g., length/width along x/y axes) than the passthrough die 106 and the memory dies 104a-h. Alternatively, in some embodiments, the base die 102 and the passthrough die 106 may have a larger size (e.g., length/width along x/y axes) than the memory dies 104a-h. In these embodiments, the smaller dies (e.g., the passthrough die 106 and/or the memory dies 104a-h) may have sidewalls made of encapsulant materials (e.g., epoxy) to match the dimensions of the larger die(s) (e.g., the base die 102 and/or the passthrough die 106).

In some embodiments, stacked memory chip 100 may be a high-bandwidth memory (HBM) chip, and the respective memory dies 104a-h may include dynamic random access memory (DRAM).

In various embodiments, the base die 102 and the memory dies 104a-h may be oriented with their circuitry facing up or facing down in the stacked memory chip 100.

Stacked memory chip 100 may also be referred to as stacked memory, memory, a memory stack, high-bandwidth memory (HBM), an HBM chip, an HBM stack, an integrated circuit (IC), a microelectronic assembly, an electronic device, and variations thereof.

It should be appreciated that stacked memory chip 100 is merely shown as an example and numerous variations and alternative embodiments are also within the scope of this disclosure. In various embodiments, for example, certain elements of stacked memory chip 100 may be modified, replaced, rearranged, omitted, and/or added. As an example, stacked memory chip 100 may include any number of stacked memory dies 104. Stacked memory chip 100 may also use any suitable interconnect technology for the respective interconnects 101, 103 above, below, and/or between the dies 102, 104a-h, 106, including, without limitation, hybrid bond interconnects (HBI), micro ball grid array (μBGA) interconnects, and ball grid array (BGA) interconnects. Stacked memory chip 100 may also include other elements not shown in the illustrated embodiment for the sake of simplicity.

The concepts described above for stacked memory chip 100, including any modifications thereof, also apply to the other embodiments in this disclosure (and vice versa), including stacked memory chips 200, 300 and system 500. Further, while the described embodiments are directed to stacked memory, the same concepts apply equally to any integrated circuit product with stacked dies.

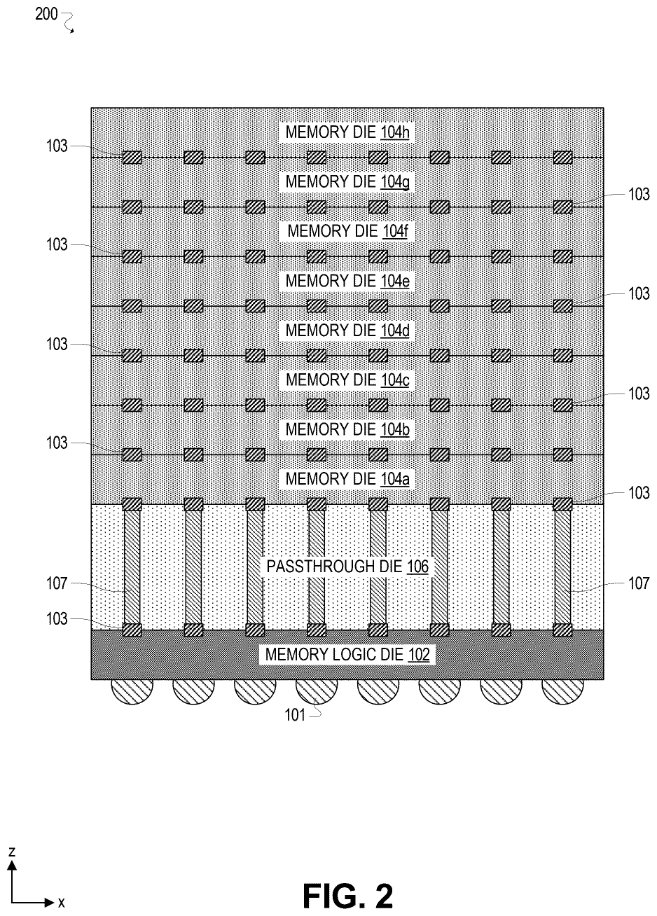

FIG. 2 illustrates a cross-section (x-z plane) view of a stacked memory chip 200 with a thicker passthrough die 106 and iso-height memory dies 104a-h. In the illustrated embodiment, stacked memory chip 200 is similar to stacked memory chip 100, except the thickness of the passthrough die 106 is increased while the thickness of the top memory die 104h is reduced. As a result, stacked memory chip 200 has a thicker passthrough die 106 and iso-height memory dies 104a-h (e.g., memory dies with uniform height/thickness), with the same overall height or thickness as chip 100 (e.g., along the z axis).

Thus, in stacked memory chip 200, the passthrough die 106 is thicker than the respective memory dies 104a-h, and the respective memory dies 104a-h have substantially the same height or thickness. As a result, by increasing the thickness of the passthrough die 106, the heat spreading efficiency in the passthrough die 106 is increased even further (e.g., at the cost of reduced heat spreading in the thinner top memory die 104h).

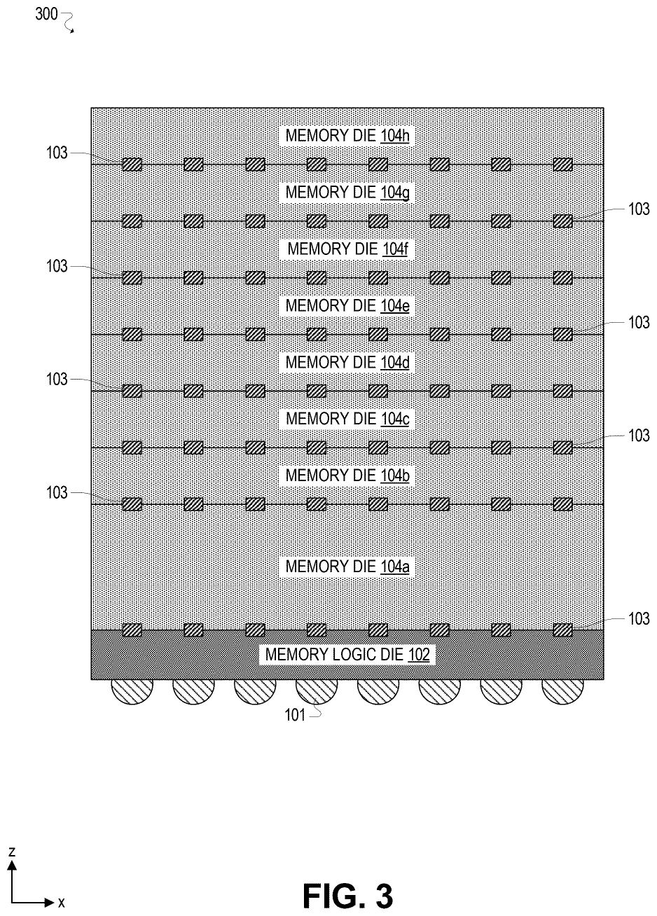

FIG. 3 illustrates a cross-section (x-z plane) view of a stacked memory chip 300 with memory dies 104a-h that have non-uniform thickness based on power requirements. In the illustrated embodiment, stacked memory chip 300 is similar to stacked memory chip 100, except the passthrough die 106 is omitted, and instead, stacked memory chip 300 includes memory dies 104a-h with non-uniform thickness, where the thickness of the respective memory dies 104a-h varies based on the amount of power they require. For example, the higher the power of a memory die 104a, the higher the thickness of that memory die 104a relative to the other memory dies 104b-h, such that the highest-power memory die 104a (e.g., the memory die 104a that requires the most power) is the thickest.

In the illustrated embodiment, for example, the first (e.g., lowest or bottom) memory die 104a in the stack requires more power than the other memory dies 104b-h due to a higher frequency of read/write operations on that die 104a. As a result, since the first memory die 104a has the highest power and generates the most heat, the first memory die 104a is thicker than the other memory dies 104b-h to enhance heat spreading in that die 104a. In the illustrated embodiment, the remaining (thinner) memory dies 104b-h have substantially uniform thickness, as their respective power requirements are relatively similar to each other. In other embodiments, however, the remaining memory dies 104b-h may similarly have varying thicknesses based on their respective power requirements.

In the illustrated embodiment, since the passthrough die 106 is omitted, the base memory logic die 102 is attached and conductively coupled to the first (e.g., lowest or bottom) memory die 104a in the stack, and adjacent memory dies 104a-h in the stack are attached and conductively coupled to each other. The respective dies 102, 104a-h may be attached and conductively coupled to each other using any suitable interconnect technology, such as hybrid bond interconnects (HBI) and/or bump interconnects (e.g., BGA, micro-BGA (μBGA)).

In other embodiments, however, stacked memory chip 300 may include a passthrough die 106 (e.g., between the base logic die 102 and the first memory die 104a) in addition to the memory dies 104a-h with non-uniform thicknesses that vary based on power requirements.

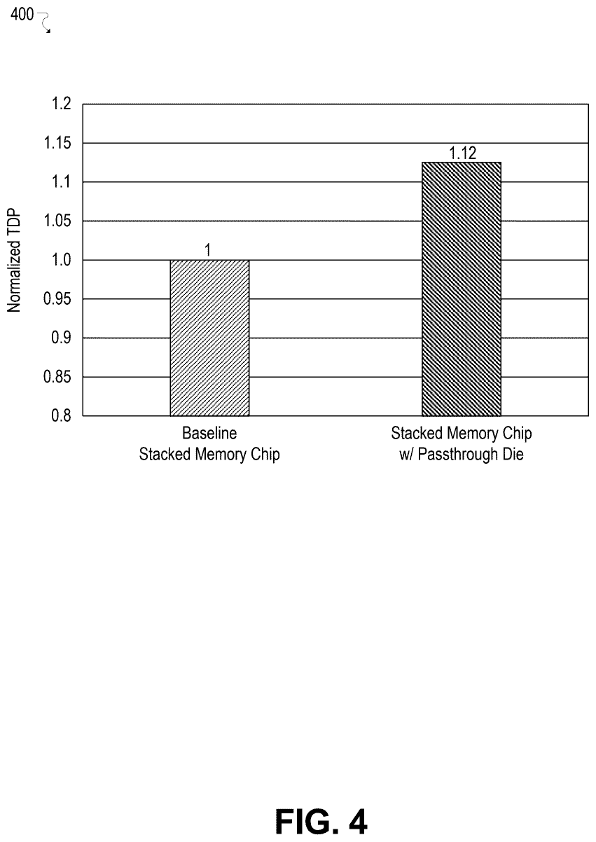

FIG. 4 illustrates a graph 400 showing the normalized thermal design power (TDP) of stacked memory chips with and without a passthrough die. As shown in graph 400, the baseline stacked memory chip (e.g., without a passthrough die) has a normalized TDP of 1.0, while the stacked memory chip with a passthrough die has a normalized TDP of 1.12, which reflects a 12% increase in TDP for the stacked memory chip with a passthrough die (given the same thermal budget for both stacked memory chips). Thus, in this example, the addition of the passthrough die increased TDP for the stacked memory chip by 12%.

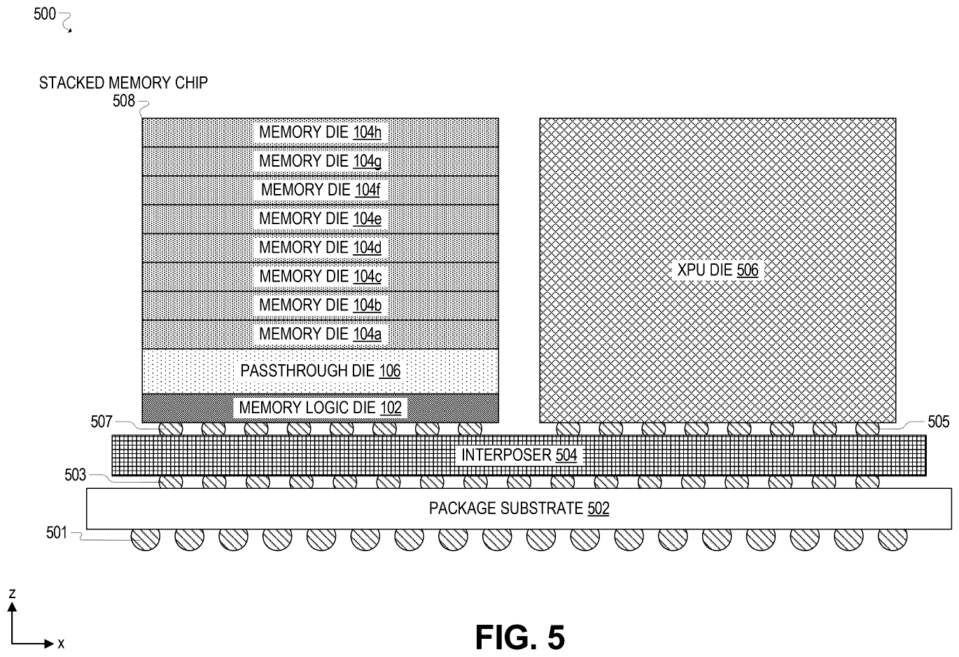

FIG. 5 illustrates a cross-section (x-z plane) view of an example system 500 with a stacked memory chip 508. System 500 may also be referred to as an electronic device, an integrated circuit (IC), an IC package, a microelectronic assembly, and variations thereof.

In the illustrated embodiment, system 500 includes an XPU die 506 and an associated stacked memory chip 508, which are attached and conductively coupled to an interposer 504 via respective bump interconnects 505, 507 (e.g., conductive bumps/microbumps) in close proximity to each other. In turn, the interposer 504 is attached and conductively coupled to a package substrate 502 via another bump interconnect 503. The package substrate 502 includes another bump interconnect 501 on the backside, which is used to conductively couple the package substrate 502 to another component (not shown). In some embodiments, for example, the backside of the package substrate 502 may be conductively coupled to a printed circuit board (PCB) via the bump interconnect 501.

In the illustrated embodiment, the stacked memory chip 508 is implemented using a similar design as stacked memory chips 100, 200 (with some reference numerals and elements omitted for simplicity). In particular, the stacked memory chip 508 includes a base memory logic die 102, a stack of memory dies 104a-h, and a passthrough die 106 between the base die 102 and the stack of memory dies 104a-h. In other embodiments, the stacked memory chip 508 may be implemented using the design of stacked memory chip 300 (e.g., using memory dies 104a-h with non-uniform thickness based on power requirements). In some embodiments, the stacked memory chip 508 may be a high-bandwidth memory (HBM) chip or HBM stack.

In the illustrated embodiment, the XPU die 506 and the stacked memory chip 508 have substantially the same height or thickness (e.g., along the z axis), which enables the use of a common cooling solution (not shown) to simultaneously cool the XPU die 506 and the stacked memory chip 508.

The XPU 506 may include any type or combination of processing circuitry that may use the stacked memory chip 508 to read/write data. For example, the XPU 506 may include any type or combination of processing units or other computing components, including, but not limited to, microcontrollers, microprocessors, processor cores, central processing units (CPUs), graphics processing units (GPUs), vision processing units (VPUs), neural processing units (NPUs), tensor processing units (TPUs), application-specific integrated circuits (ASICs), and field-programmable gate arrays (FPGAs). The XPU die 506 may also be referred to as an XPU, processing unit, processor die, processor, processing circuitry, compute unit, compute die, and variations thereof.

The interposer 504 may include a substrate with conductive traces and vias, which collectively form electrical connections that conductively couple the XPU die 506 and the stacked memory chip 508 to each other and to the package substrate 502. In various embodiments, the interposer 504 may be passive or active and may be made of organic or inorganic (e.g., silicon) materials. In some embodiments, the interposer 504 may be omitted, and the XPU 506 and the stacked memory chip 508 may be attached and conductively coupled directly to the package substrate 502.

In some embodiments, a structural substrate (e.g., structural silicon) may be attached on top of the stacked memory chip 508 and the XPU 506 (e.g., over the total interposer 504 area). As an example, for a thin XPU die 506 and/or a thin low-height stacked memory chip 508 (e.g., 4H high-bandwidth memory 508 with four DRAM memory dies 104 a-d), a structural silicon substrate may be attached over the stacked memory chip 508 and the XPU 506 to make the die complex iso-height or otherwise to achieve a required height (e.g., 720 μm). In some embodiments, the structural silicon substrate may be attached on top of the stacked memory chip 508 and the XPU 506 using a dielectric layer, such as silicon oxide (e.g., SiO₂), which may also serve as a gap filler to fill the gap between the stacked memory chip 508 and the XPU 506.

In some embodiments, system 500 may be part of an electronic device or system, such as a mobile device, a wearable device, a computer, a server, a video playback device, a video game console, a display device, a camera, or an appliance.

It should be appreciated that system 500 is merely shown as an example and numerous variations and alternative embodiments are also within the scope of this disclosure. In various embodiments, for example, certain elements of system 500 may be modified, replaced, rearranged, omitted, and/or added. As an example, system 500 may include any number of stacked memory chips 508 and XPU dies 506. System 500 may use any interconnect technology for the respective interconnects 501, 503, 505, 507. System 500 may also include other components (not shown), such as cooling components (e.g., heat pipes, vapor chambers, cold plates) to cool the stacked memory chip 508 and/or the XPU die 506, network interfaces, storage devices, etc.

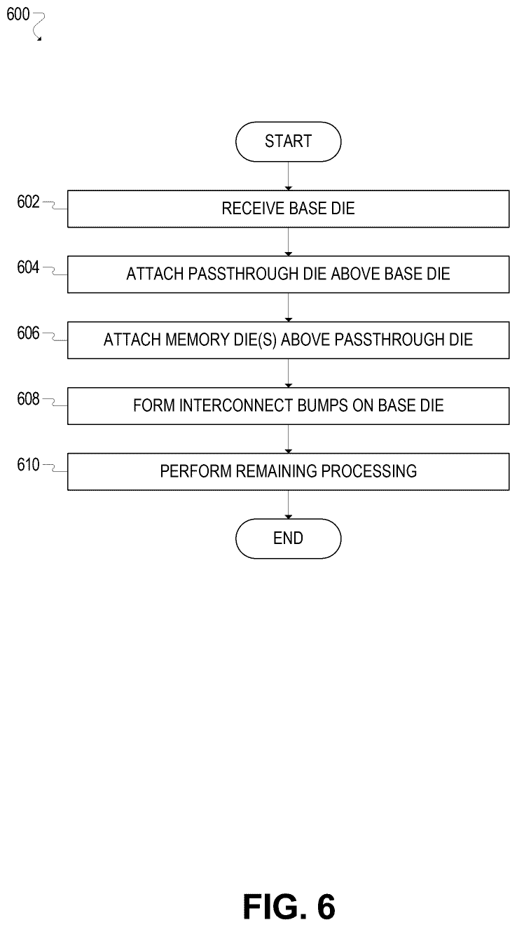

FIG. 6 illustrates a flowchart 600 for forming a stacked memory chip in accordance with certain embodiments. It will be appreciated in light of the present disclosure that the illustrated process flow is only one example methodology for arriving at the example stacked memory chips 100, 200, 300 shown and described throughout this disclosure.

The steps of the illustrated process flow may be performed using any suitable semiconductor fabrication techniques. For example, film deposition—such as depositing layers, filling portions of layers (e.g., removed portions), and filling via openings—may be performed using any suitable deposition techniques, including, for example, chemical vapor deposition (CVD), metal-organic chemical vapor deposition (MOCVD), molecular beam epitaxy (MBE), atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

The flowchart begins at block 602 by receiving a base die containing memory logic, which may also be referred to as the memory logic die.

The flowchart then proceeds to block 604 to attach a passthrough die above the base die. In some embodiments, the passthrough die may include a substrate made of a material with high thermal conductivity (e.g., silicon (Si), diamond, hexagonal boron nitride (h-BN)), along with one or more passthrough connections through the substrate (e.g., through-substrate vias (TSVs), redistribution layers (RDLs) with conductive traces and vias, etc.).

The passthrough die may be attached above the base die using any suitable interconnect technology. In some embodiments, for example, the passthrough die may be hybrid bonded to the top side of the base die, such that hybrid dielectric-to-dielectric and metal-to-metal bonds are formed at the interface between the base die and the passthrough die, thus conductively coupling the base die and the passthrough die via a hybrid bond interconnect (HBI). Alternatively, in some embodiments, the base die and the passthrough die may be attached and conductively coupled to each other via a bump interconnect (e.g., micro ball grid array (μBGA) or microbump interconnect, ball grid array (BGA) interconnect, etc.).

Alternatively, in some embodiments, the passthrough die may be omitted.

The flowchart then proceeds to block 606 to attach a stack of one or more memory die(s) above the passthrough die. In this manner, the base die and the first (e.g., lowest) memory die in the stack are conductively coupled to each other through the passthrough connections in the passthrough die. The stack of memory dies may be attached above the base die using any suitable interconnect technology, such as an HBI interconnect, micro-BGA (μBGA) interconnect, or BGA interconnect.

In some embodiments, the memory dies may have non-uniform thicknesses based on their respective power requirements (e.g., where the thickest memory die has the highest power), as described throughout this disclosure. Moreover, if the passthrough die is omitted at block 604, the stack of non-uniform thickness memory dies may be attached to the base die instead of the passthrough die.

The flowchart then proceeds to block 608 to form one or more interconnect bumps on the bottom side of the base die. In particular, one or more conductive (e.g., metal, solder) bumps may be formed on the bottom side of the base die, such that they land on, and are conductively coupled to, pads or other conductive contacts on the bottom side of the base die. In this manner, the bumps can be used as an interconnect to conductively couple the base die to another IC component, such as an interposer, an IC package substrate, or a printed circuit board (PCB). In some embodiments, for example, the bumps may collectively form a ball grid array (BGA) or micro BGA (μBGA) interconnect. Alternatively, in some embodiments, one or more conductive pads may be embedded in a dielectric layer on the bottom side of the base die to enable an HBI interconnect.

The flowchart then proceeds to block 610 to perform any remaining processing. For example, in wafer-level or panel-level process flows, the resulting wafer or panel assembly may be diced to singulate the individual units of stacked memory chips on the wafer or panel assembly. The singulated chips may then be attached to, or assembled in, an IC package, a printed circuit board (PCB), and/or an electronic device or system (e.g., system 500, electronic device 1000), among other examples. In some embodiments, for example, the backside of the base die may be attached and conductively coupled to an interposer (e.g., near an associated processing unit or XPU) via interconnect bumps on the backside of the base die, the interposer may be attached and conductively coupled to a package substrate, and/or the package substrate may be attached and conductively coupled to a PCB.

At this point, the flowchart may be complete. In some embodiments, however, the flowchart may restart and/or certain blocks may be repeated. For example, in some embodiments, the flowchart may restart at block 602 to continue forming stacked memory chips with the same or similar design.

### EXAMPLE INTEGRATED CIRCUIT EMBODIMENTS

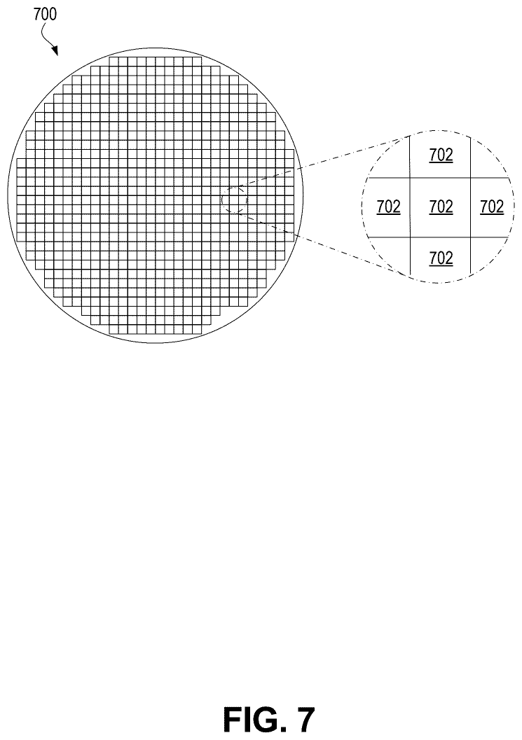

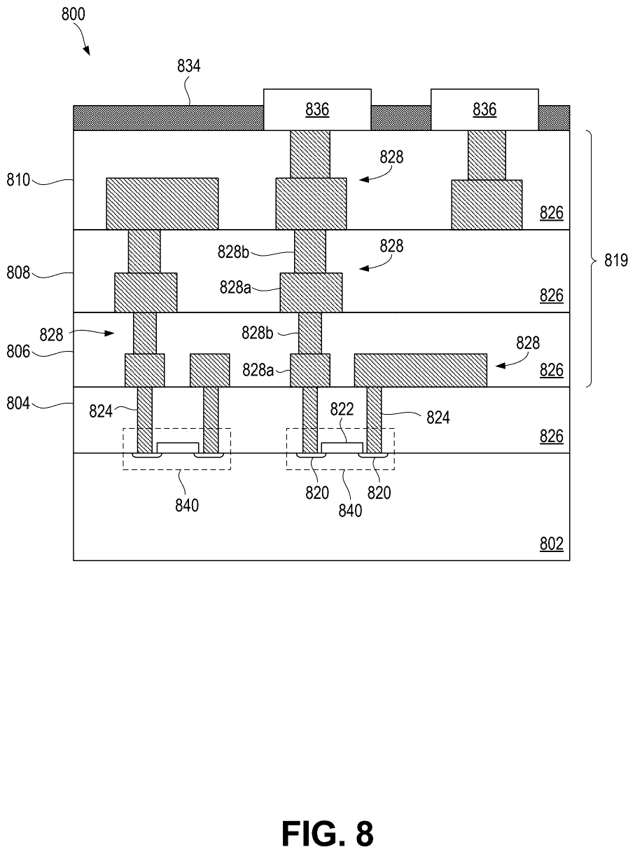

FIG. 7 illustrates a top view of a wafer 700 and dies 702 that may be included in any of the embodiments 100, 200, 300, 500 disclosed herein (e.g., as any suitable ones of the dies 102, 104, 106, 502, 504, 506). The wafer 700 may be composed of semiconductor material and dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The dies 702 may be any of the dies disclosed herein. The dies 702 may include one or more transistors (e.g., transistors 840 of FIG. 8, discussed below), supporting circuitry to route electrical signals to the transistors, passive components (e.g., signal traces, resistors, capacitors, or inductors), and/or any other integrated circuit components that can be fabricated on the wafer. In some embodiments, the wafer 700 or the dies 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), logic gates (e.g., AND, OR, NAND, and NOR gates), or any other suitable circuit element. Multiple ones of these devices and components may be combined on a single die. For example, a memory array formed by multiple memory devices may be formed on the same die as a processor unit or other logic configured to store information in the memory devices or execute instructions stored in the memory array. Some of the embodiments 100, 200, 300, 500 disclosed herein may be manufactured using a die-to-wafer assembly technique in which some dies are attached to a wafer 700 that includes others of the dies, and the wafer 700 is subsequently singulated. Alternatively, or additionally, some of the embodiments 100, 200, 300, 500 disclosed herein may be manufactured using a wafer-to-wafer assembly technique in which multiple wafers 700 with dies 702 are stacked and attached together, and the stack of wafers 700 is subsequently singulated.

FIG. 8 illustrates a cross-sectional view of an integrated circuit structure 800 that may be included in any of the embodiments 100, 200, 300, 500 disclosed herein (e.g., in any of the dies 102, 104, 106, 502, 504, 506, 702). Multiple instances of the integrated circuit structure 800 may be included in the dies 702 (FIG. 7). The integrated circuit structure 800 may be formed on a die substrate 802. The die substrate 802 may be a semiconductor substrate composed of semiconductor material including, for example, n-type or p-type materials (or a combination of both). The die substrate 802 may include, for example, a crystalline substrate formed using a bulk silicon or a silicon-on-insulator (SOI) substructure. In some embodiments, the die substrate 802 can comprise a layer of silicon on top of an SOI layer with bulk silicon below the SOI layer. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit structure 800 may be used. The die substrate 802 may be part of a singulated die (e.g., dies 702 of FIG. 7) or a wafer (e.g., wafer 700 of FIG. 7).

The integrated circuit structure 800 may include device layer 804 disposed on the die substrate 802. The device layer 804 may include features of transistors 840 (e.g., metal oxide semiconductor field-effect transistors (MOSFETs)) formed on the die substrate 802. The transistors 840 may include, for example, source and drain regions (S/D regions 820), a gate 822 to control current flow between the S/D regions 820, and S/D contacts 824 to route electrical signals to and from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, non-planar transistors, or a combination of planar and non-planar transistors. Non-planar transistors may include FinFET transistors, such as double-gate transistors or tri-gate transistors, and wrap-around or all-around gate transistors, such as nanoribbon, nanosheet, or nanowire transistors.

Transistors 840 may include a gate 822 formed of at least two layers, a gate dielectric, and a gate electrode. The gate dielectric may include one or more layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For PMOS transistors, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For NMOS transistors, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, such as a FinFET, the gate electrode may have an upside-down U-shape that includes a top portion substantially parallel to the surface of the die substrate 802 and two side portions that are substantially perpendicular to the top surface of the die substrate 802. In other embodiments, such as a planar FET, at least one of the metal layers that form the gate electrode may be a planar layer that is substantially parallel to the top surface of the die substrate 802 without side portions. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack (comprising the gate dielectric and the gate electrode) to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of sidewall spacer pairs may be used; for instance, two pairs, three pairs, or four pairs of sidewall spacers may be formed on opposing sides of the gate stack.

The S/D regions 820 may be formed within the die substrate 802 adjacent to the gate 822 of transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse further into the die substrate 802 may follow the ion implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or information-carrying signals (e.g., input/output (I/O) signals, may be routed to and/or from devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with interconnect structures 828 of the interconnect layers 806-810. The one or more interconnect layers 806-810 may form a metallization stack 819 (which can also be referred to as an “ILD stack” (inter-layer dielectric stack)) of the integrated circuit structure 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit structures having more or fewer interconnect layers than depicted.

In some embodiments, the interconnect structures 828 may include traces or lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page from the perspective of FIG. 8. The vias 828b may be arranged to route electrical signals in a direction of a plane that is substantially perpendicular to the surface of the die substrate 802 upon which the device layer 804 is formed. In some embodiments, lines 828a of different interconnect layers 806-810 are electrically coupled by vias 828b.

The interconnect layers 806-810 may include a dielectric material 826 within which the interconnect structures 828 are disposed, as shown in FIG. 8. In some embodiments, dielectric material 826 in different ones of the interconnect layers 806-810 may have different compositions; in other embodiments, the composition of the dielectric material 826 between different interconnect layers 806-810 may be the same. The device layer 804 may include a dielectric material 826 within which the transistors 840 are disposed and upon which a bottom layer of the metallization stack is located. The dielectric material 826 that is part of the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (which can be referred to as a Metal 1 or “M1” layer) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (which can be referred to as a Metal 2 or “M2” layer) may be formed directly on the first interconnect layer 806. In some embodiments, the second interconnect layer 808 may include vias 828b to couple the lines 828a of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (which can be referred to as a Metal 3 or “M3” layer) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit structure 800 (i.e., farther away from the device layer 804) may be thicker than the interconnect layers that are lower in the metallization stack 819, with lines 828a and vias 828b in the higher interconnect layers being thicker than those in the lower interconnect layers.

The integrated circuit structure 800 may include a solder resist material 834 (e.g., polyimide or similar material) and conductive contacts 836 formed on the stack of interconnect layers 806-810. In FIG. 8, the conductive contacts 836 are illustrated as taking the form of bond pads. The conductive contacts 836 may be electrically coupled with interconnect structures 828 of the top-most layer in the metallization stack 819 and configured to route electrical signals between the transistors 840 and components external to the integrated circuit structure 800. For example, solder bonds may be formed on the conductive contacts 836 to mechanically and/or electrically couple an integrated circuit component comprising the integrated circuit structure 800 with another component (e.g., a printed circuit board). The integrated circuit structure 800 may include additional or alternate structures to route electrical signals from the interconnect layers 806-810; for example, the conductive contacts 836 may include other analogous features (e.g., posts) that can route the electrical signals between the transistors 840 and external components.

In some embodiments in which the integrated circuit structure 800 is part of a double-sided die, the integrated circuit structure 800 may include a second metallization stack (not shown) located on the opposite side of the die substrate 802 from the device layer 804. This second metallization stack may include multiple interconnect layers as discussed above with reference to the interconnect layers 806-810. Through-silicon vias (TSVs) that extend through the die substrate 802 can provide electrically conductive pathways from the transistors 840 to the second metallization stack and the second metallization stack can electrically couple the TSVs to additional conductive contacts (not shown) located on the opposite side of the integrated circuit structure 800 from the conductive contacts 836.

In some embodiments, TSVs extending through the die substrate 802 can be used for routing power and ground signals from conductive contacts located on the opposite side of the integrated circuit structure 800 from the conductive contacts 836 to the transistors 840 and any other components integrated into the integrated circuit structure 800, and the metallization stack 819 can be used to route information-carrying signals from the conductive contacts 836 to transistors 840 and any other components integrated into the integrated circuit structure 800. Put another way, the routing of power and ground signals to the transistors 840 can be separated (via a back-side or bottom-side metallizaton stack and TSVs) from the routing of information-carrying signals to the transistors. The power and ground signals are provided by a backside or bottom-side metallization stack and TSVs, and information-carrying signals are provided by a topside metallization stack (e.g., metallization stack 819).

Several integrated circuit dies may be stacked with one or more TSVs in the individual stacked dies providing connection between one of the dies to any of the other dies in the stack. For example, one or more high-bandwidth memory (HBM) integrated circuit dies can be stacked on top of a base integrated circuit die and TSVs in the HBM dies can provide connection between the individual HBM dies and the base integrated circuit die. Conductive contacts can provide additional connections between adjacent integrated circuit dies in the stack. In some embodiments, the conductive contacts can be fine-pitch solder bumps (microbumps).

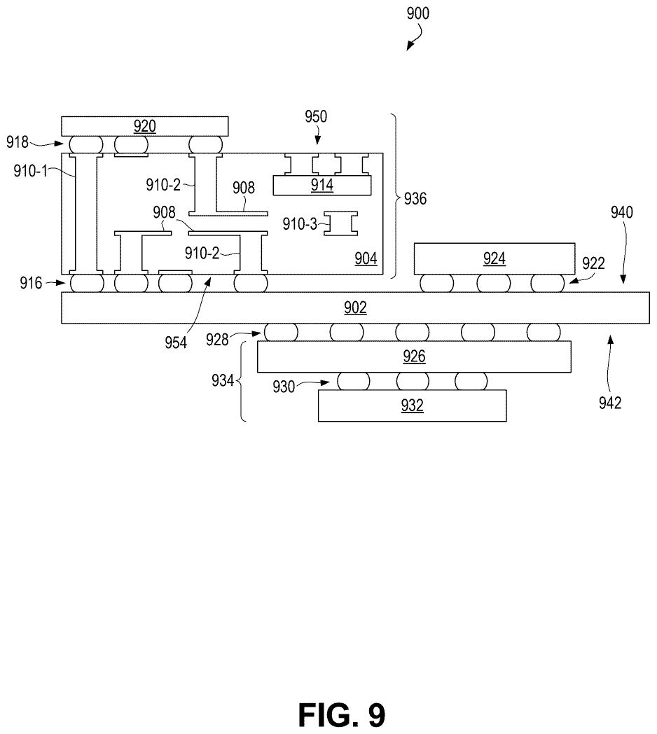

FIG. 9 illustrates a cross-sectional view of an integrated circuit device assembly 900 that may include any of the embodiments 100, 200, 300, 500 disclosed herein. In some embodiments, for example, the embedded devices 914 and/or IC components 920, 924, 926, 932 of the integrated circuit device assembly 900 may include one or more stacked memory chips 100, 200, 300. In some embodiments, the integrated circuit device assembly 900 may be a microelectronic assembly. The integrated circuit device assembly 900 includes a number of components disposed on a circuit board 902 (which may be a motherboard, system board, mainboard, etc.). The integrated circuit device assembly 900 includes components disposed on a first face 940 of the circuit board 902 and a second face 942 of the circuit board 902, the second face 942 opposing the first face 940. Generally, components may be disposed on either or both of the first face 940 and the second face 942 of the circuit board 902. Any of the integrated circuit components discussed below with reference to the integrated circuit device assembly 900 may take the form of any suitable ones of the embodiments of the microelectronic assemblies 100, 200, 300, 500 disclosed herein.

In some embodiments, the circuit board 902 may be a printed circuit board (PCB) including multiple metal (or interconnect) layers separated from one another by layers of dielectric material and interconnected by electrically conductive vias. The individual metal layers comprise conductive traces. The metal layers may be formed in a desired pattern to route electrical signals between the components electrically coupled to the circuit board 902. In other embodiments, the circuit board 902 may be a non-PCB substrate. In some embodiments, for example, the circuit board 902 may be an interposer 504 or a package substrate 502.

The integrated circuit device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902 and may include solder balls (as shown in FIG. 9), pins (e.g., as part of a pin grid array (PGA), contacts (e.g., as part of a land grid array (LGA)), hybrid bond interconnect (HBI) pads, male and female portions of a socket, an adhesive, an underfill material, and/or any other suitable electrical and/or mechanical coupling structure (e.g., a conductive contact). The coupling components 916 may serve as the coupling components illustrated or described for any substrate assembly or substrate assembly components described herein (e.g., integrated circuit components), as appropriate.

The package-on-interposer structure 936 may include an integrated circuit component 920 coupled to an interposer 904. The interposer 904 may provide an intervening substrate used to bridge the circuit board 902 and the integrated circuit component 920. The integrated circuit component 920 is coupled to the interposer 904 by coupling components 918. The coupling components 918 may take any suitable form, such as the forms discussed above with reference to the coupling components 916. Although FIG. 9 shows just one integrated circuit component attached to the interposer, multiple integrated circuit components may be coupled to the interposer 904. Additional interposers may be coupled to the interposer 904.

The integrated circuit component 920 may be a packaged or unpackaged integrated circuit product that includes one or more integrated circuit dies (e.g., the die 702 of FIG. 7, a die comprising the integrated circuit structure 800 of FIG. 8) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one unpackaged example of an integrated circuit component 920, a single monolithic integrated circuit die comprises solder bumps attached to contacts on the die. The solder bumps allow the die to be directly attached to the interposer 904. The integrated circuit component 920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 920 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 904 may spread connections to a wider or narrower pitch or reroute a connection to a different connection. For example, the interposer 904 may couple coupling components 918 having a first pitch to coupling components 916 having a wider pitch than the first pitch. In the embodiment illustrated in FIG. 9, the integrated circuit component 920 and the circuit board 902 are attached to opposing sides of the interposer 904. In other embodiments, the integrated circuit component 920 and the circuit board 902 may be attached to a same side of the interposer 904. In some embodiments, three or more components may be interconnected by way of the interposer 904.

In some embodiments, the interposer 904 may be formed as a PCB, including multiple metal layers separated from one another by layers of dielectric material and interconnected by electrically conductive vias. In some embodiments, the interposer 904 may be formed of an epoxy resin, a fiberglass-reinforced epoxy resin, an epoxy resin with inorganic fillers, a ceramic material, or a polymer material such as polyimide. In some embodiments, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias, including but not limited to through hole vias 910-1 (that extend from a first face 950 of the interposer 904 to a second face 954 of the interposer 904), blind vias 910-2 (that extend from the first face 950 or the second face 954 of the interposer 904 to an internal metal layer), and buried vias 910-3 (that connect internal metal layers).

In some embodiments, the interposer 904 can comprise a silicon interposer. Through silicon vias (TSV) extending through the silicon interposer can connect connections on a first face of a silicon interposer to an opposing second face of the silicon interposer. In some embodiments, an interposer 904 comprising a silicon interposer can further comprise one or more routing layers to route connections on a first face of the interposer 904 to an opposing second face of the interposer 904.

In some embodiments, certain components of assembly 900 (e.g., interposer 904, circuit board 902, IC components 920, 924, 926, 932) may include an amorphous solid layer of glass (which can be referred to a glass core or glass substrate). In some embodiments, the layer of glass can comprise silica (comprising silicon dioxide (SiO₂)), fused silica, aluminosilicate (comprising aluminum oxide (Al₂O₃) and silicon dioxide), borosilicate (comprising silicon dioxide and boron trioxide (B₂O₃)), or alumino-borosilicate (comprising aluminum oxide, silicon dioxide, and boron trioxide). In some embodiments, the layer of glass can comprise one or more of the following additives: aluminum oxide, boron trioxide, magnesium oxide (MgO), calcium oxide (CaO), strontium oxide (SrO), barium oxide (BaO), tin(IV) oxide (SnO₂), nitrous oxide (Na₂O), potassium oxide (K₂O), diphosphorous trioxide (P₂O₃), zirconium dioxide (ZrO₂), lithium oxide (Li₂O), titanium, and zinc. In some embodiments, the layer of glass can comprise silicon and oxygen, as well as one or more of aluminum, boron, magnesium, calcium, barium, tin, sodium, potassium, strontium, phosphorous, zirconium, lithium, titanium, and zinc. In some embodiments, the layer of glass comprises at least 23 percent silicon by weight, at least 26 percent oxygen by weight, and at least five percent aluminum by weight. In some embodiments, the layer of glass does not include an organic adhesive or an organic material. For example, the layer of glass is not a substrate or a board comprising glass fibers and an epoxy binder, such as a printed circuit board (PCB) comprising multiple metal (or interconnect) layers separated from one another by layers of dielectric material (e.g., FR-4 or other fiberglass-reinforced epoxy laminate) and interconnected by electrically conductive vias.

In some embodiments, the glass layer has a thickness in the range of about 50 microns to about 1.4 millimeters. In some embodiments, the glass layer is or is part of a multi-layer glass substrate (a coreless substrate). Individual glass layers in a multi-layer glass substrate can have a thickness in the range of about 25 microns to about 50 microns. In some embodiments, a glass layer can have a length in the range of about 10 millimeters to about 250 millimeters on a side (e.g., can have an area in the range of about 10 mm×10 mm to about 250 mm×250 mm). In some embodiments, the glass layer comprises a rectangular prism volume with sections or portions (e.g., through-glass vias) removed and filled with other metals (e.g., metal).

In some embodiments, redistribution layers (RDL) can be located on either or both sides of the glass layer to provide electrically conductive paths from top and/or bottom surfaces of the interposer 904 or circuit board 902 to the glass layer. The glass layer can comprise through-glass vias (TGVs) that extend through the glass layer to provide electrically conductive paths through the glass core, glass substrate, or glass layer.

The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art.

The integrated circuit device assembly 900 may include an integrated circuit component 924 coupled to the first face 940 of the circuit board 902 by coupling components 922. The coupling components 922 may take the form of any of the embodiments discussed above with reference to the coupling components 916, and the integrated circuit component 924 may take the form of any of the embodiments discussed above with reference to the integrated circuit component 920.

The integrated circuit device assembly 900 illustrated in FIG. 9 further includes a package-on-package structure 934 coupled to the second face 942 of the circuit board 902 by coupling components 928. The package-on-package structure 934 may include an integrated circuit component 926 and an integrated circuit component 932 coupled together by coupling components 930 such that the integrated circuit component 926 is disposed between the circuit board 902 and the integrated circuit component 932. The coupling components 928 and 930 may take the form of any of the embodiments of the coupling components 916 discussed above, and the integrated circuit components 926 and 932 may take the form of any of the embodiments of the integrated circuit component 920 discussed above. The package-on-package structure 934 may be configured in accordance with any of the package-on-package structures known in the art.

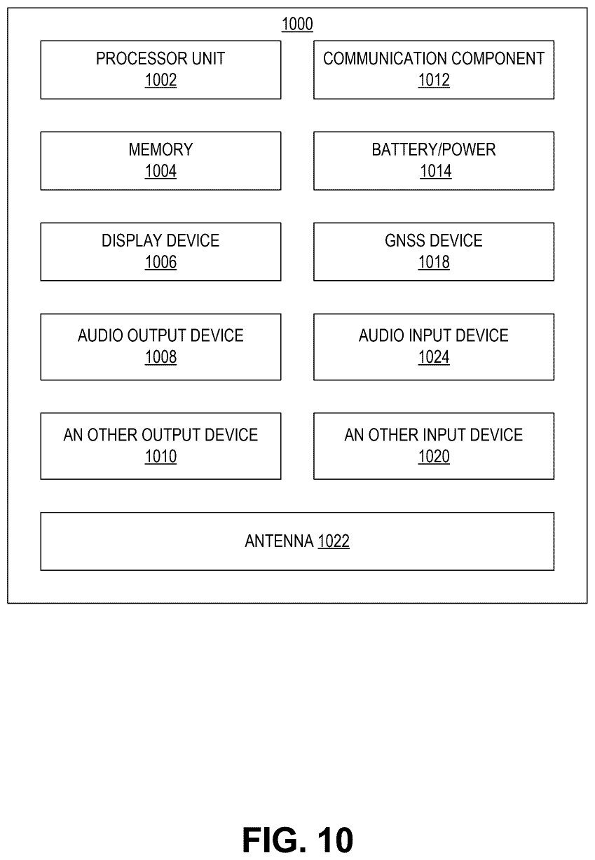

FIG. 10 illustrates a block diagram of an example electrical device 1000 that may include any of the embodiments disclosed herein. For example, any suitable ones of the components of the electrical device 1000 may include one or more of the stacked memory chips 100, 200, 300, integrated circuit device assembly 900, integrated circuit component 920, integrated circuit structure 800, or integrated circuit dies 702 disclosed herein, and may be arranged in any of the microelectronic assemblies 100, 200, 300, 500 disclosed herein. A number of components are illustrated in FIG. 10 as included in the electrical device 1000, but any one or more of these components may be omitted or duplicated, as suitable for the application. In some embodiments, some or all of the components included in the electrical device 1000 may be attached to one or more motherboards mainboards, or system boards. In some embodiments, one or more of these components are fabricated onto a single system-on-a-chip (SoC) die.

Additionally, in various embodiments, the electrical device 1000 may not include one or more of the components illustrated in FIG. 10, but the electrical device 1000 may include interface circuitry for coupling to the one or more components. For example, the electrical device 1000 may not include a display device 1006, but may include display device interface circuitry (e.g., a connector and driver circuitry) to which a display device 1006 may be coupled. In another set of examples, the electrical device 1000 may not include an audio input device 1024 or an audio output device 1008, but may include audio input or output device interface circuitry (e.g., connectors and supporting circuitry) to which an audio input device 1024 or audio output device 1008 may be coupled.

The electrical device 1000 may include one or more processor units 1002. As used herein, the terms “processor unit,” “processing unit,” or “processor” may refer to any device or portion of a device that processes electronic data from registers and/or memory to transform that electronic data into other electronic data that may be stored in registers and/or memory. The one or more processor units 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the one or more processor units 1002. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments of the electrical device 1000, a first one of the one or more processor units 1002 can be heterogeneous or asymmetric to a second one of the one or more processor units 1002 in the electrical device 1000. There can be a variety of differences between the one or more processor units 1002 in a system in terms of a spectrum of metrics of merit including architectural, microarchitectural, thermal, power consumption characteristics, and the like. These differences can effectively manifest themselves as asymmetry and heterogeneity among the one or more processor units 1002 in the electrical device 1000.

In some embodiments, the electrical device 1000 may include a communication component 1012. For example, the communication component 1012 can manage wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP 2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electrical device 1000 may include an antenna 1022 to facilitate wireless communications and/or to receive other wireless communications (such as AM or FM radio transmissions).

In some embodiments, the communication component 1012 may manage wired communications, such as electrical, optical, or any other suitable communication protocols (e.g., IEEE 802.3 Ethernet standards). In some embodiments, the electrical device 1000 comprises multiple communication components. For instance, a first communication component may be dedicated to shorter-range wireless communications such as Wi-Fi or Bluetooth, and a second communication component may be dedicated to longer-range wireless communications such as global positioning system (GPS), EDGE, GPRS, CDMA, WiMAX, LTE, EV-DO, or others. In some embodiments, a first communication component may be dedicated to wireless communications, and a second communication component may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any embedded or wired or wirelessly connected external device that generates an audible indicator, such as speakers, headsets, or earbuds.

The electrical device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electrical device 1000 may include a Global Navigation Satellite System device (GNSS) (or corresponding interface circuitry, as discussed above), such as a Global Positioning System (GPS) device. The GNSS device 1018 may be in communication with a satellite-based system and may determine a geolocation of the electrical device 1000 based on information received from one or more GNSS satellites, as known in the art.

The electrical device 1000 may include another output device 1010 (or corresponding interface circuitry, as discussed above). Examples of the other output device 1010 may include an audio codec, a video codec, a printer, a wired or wireless transmitter for providing information to other devices, or an additional storage device.

The electrical device 1000 may include another input device 1020 (or corresponding interface circuitry, as discussed above). Examples of the other input device 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1000 may have any form factor, such as a hand-held or mobile electrical device (e.g., a cell phone, a smartphone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console), a desktop electrical device, a server, a rack-level computing solution (e.g., blade, tray, or sled computing system), a workstation or other networked computing component, a printer, a scanner, a display device (e.g., monitor, television), a set-top box, a video playback device, an entertainment control unit, a stationary gaming console, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the drawings. Additionally, the inclusion of a structural or method feature in a particular drawing is not meant to imply that such feature is required in all embodiments and, in some embodiments, such feature may not be included or may be combined with other features. Further, it should be understood that the various embodiments shown in the drawings are illustrative representations and are not necessarily drawn to scale. In some instances, the same or similar reference numerals may be used to designate the same or similar features in different drawings.

The illustrations and/or descriptions of various embodiments may be simplified, approximated, or idealized for ease of understanding, and as a result, they may not necessarily reflect the level of precision nor variation that may be present in actual embodiments. For example, while some drawings generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

As used herein, references to an “embodiment” or “embodiments” may refer to one or more of the same or different embodiments. Some embodiments may have some, all, or none of the features described for other embodiments.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

As used herein, a list of items joined by the phrase “and/or” can mean any combination of the listed items. For example, the phrase “A, B, and/or C” can mean A; B; C; A and B; A and C; B and C; or A, B and C. As used herein, a list of items referenced by the phrase “at least one of” or the phrase “one or more of” can mean any combination of the listed items. For example, the phrase “at least one of A, B, or C” or the phrase “one or more of A, B, or C” can mean A; B; C; A and B; A and C; B and C; or A, B, and C.

The terms “substantially,” “close,” “approximately,” “near,” “about”, and the like may refer to being within +/−10% of a target value unless otherwise specified. Similarly, terms describing spatial relationships, such as “perpendicular,” “orthogonal,” or “coplanar,” may refer to being substantially within the described spatial relationships (e.g., within +/−10 degrees of orthogonality).

Certain terminology may be used in the foregoing description for the purpose of reference only, and thus is not intended to be limiting. For example, terms such as “upper,” “lower,” “above,” “below,” “bottom,” and “top” may refer to directions in the drawings to which reference is made. Terms such as “front,” “back,” “rear,” and “side” may describe the orientation and/or location of portions of a feature within a consistent but arbitrary frame of reference, which may be made clear by reference to the description and drawings associated with that feature. Such terminology may include the words specifically mentioned above, derivatives thereof, and words of similar import.

As used herein, the phrase “located on” in the context of a first feature located on a second feature refers to the first feature being in direct or indirect physical contact with the second feature (e.g., with or without one or more intervening features between the first and second features).

As used herein, the term “adjacent” refers to features that are arranged next to each other (e.g., side by side, top and bottom) with or without one or more intervening features between them.

As used herein, the terms “coupled” and “connected” may refer to a direct or indirect coupling or connection (e.g., with or without one or more intervening elements).

As used herein, the phrase “electrically coupled” refers to the presence of one or more electrically conductive paths between components that are recited as being electrically coupled.

As used herein, the phrase “thermally coupled” refers to components that are coupled to facilitate the transfer of heat.

As used herein, an “integrated circuit” may refer to a packaged or unpackaged integrated circuit product. In one example, a packaged integrated circuit may include one or more integrated circuit dies mounted on a package substrate with the integrated circuit dies and package substrate encapsulated in a casing material, such as a metal, plastic, glass, or ceramic. In one example, a packaged integrated circuit may include one or more processor units mounted on a substrate with an exterior surface of the substrate comprising a solder ball grid array (BGA). In one example of an unpackaged integrated circuit, a single monolithic integrated circuit die may include solder bumps attached to contacts on the die, such that the solder bumps allow the die to be directly attached to a printed circuit board or other substrate. An integrated circuit may include one or more of any computing system component, such as a processor unit (e.g., system-on-a-chip (SoC), processor core, graphics processor unit (GPU), accelerator, chipset processor), input/output (I/O) controller, memory, network interface controller, or any other computing system component described or referenced herein.

The embodiments described herein can be implemented in any integrated circuit (e.g., packaged or unpackaged). In some embodiments, an integrated circuit implemented with the described embodiments may be attached to a printed circuit board. Moreover, in some embodiments, one or more additional components (e.g., other integrated circuits, a battery, an antenna) may also be attached to the printed circuit board. In some embodiments, the printed circuit board and the integrated circuit can be located in a computing device having a housing that encloses the printed circuit board and the integrated circuit.

The described embodiments may be implemented, in some cases, in hardware, firmware, software, or any combination thereof. The disclosed embodiments may also be implemented as instructions carried by or stored on one or more transitory or non-transitory machine-readable (e.g., computer-readable) storage media, which may be read and executed by one or more processors. A machine-readable storage medium may be embodied as any storage device, mechanism, or other physical structure for storing or transmitting information in a form readable by a machine, including volatile or non-volatile memory (e.g., random access memory (RAM), flash memory), hard drives (e.g., hard disk drive (HDD), solid state drive (SSD)), media discs, or combinations thereof.

### EXAMPLES

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a microelectronic assembly, comprising: a logic die; a stack of memory dies above the logic die, wherein the stack of memory dies comprises a plurality of memory dies stacked vertically; and a passthrough die between the logic die and the stack of memory dies, wherein the logic die is conductively coupled to the stack of memory dies through the passthrough die.

Example 2 includes the microelectronic assembly of Example 1, wherein the passthrough die is thicker than at least some of the respective memory dies.

Example 3 includes the microelectronic assembly of any of Examples 1-2, wherein: the respective memory dies have substantially a same thickness; and the passthrough die is thicker than the respective memory dies.

Example 4 includes the microelectronic assembly of any of Examples 1-2, wherein: a top memory die in the stack of memory dies is thicker than other memory dies in the stack of memory dies, wherein the top memory die does not comprise through-silicon vias; and the passthrough die is thicker than at least the other memory dies in the stack of memory dies.

Example 5 includes the microelectronic assembly of any of Examples 1-4, wherein at least some of the memory dies comprise one or more through-silicon vias.

Example 6 includes the microelectronic assembly of any of Examples 1-5, wherein the passthrough die comprises a substrate and one or more vias, wherein the one or more vias extend through the substrate.

Example 7 includes the microelectronic assembly of Example 6, wherein the substrate comprises (i) silicon, (ii) diamond, or (iii) boron and nitrogen.

Example 8 includes the microelectronic assembly of any of Examples 6-7, wherein the passthrough die further comprises one or more conductive traces.

Example 9 includes the microelectronic assembly of any of Examples 6-8, wherein the passthrough die further comprises active circuitry.

Example 10 includes the microelectronic assembly of any of Examples 1-9, wherein the passthrough die is a passive interposer or an active interposer.

Example 11 includes the microelectronic assembly of any of Examples 1-10, wherein: the logic die is conductively coupled to a first side of the passthrough die; and a bottom memory die in the stack of memory dies is conductively coupled to a second side of the passthrough die.

Example 12 includes the microelectronic assembly of any of Examples 1-11, wherein: the logic die is conductively coupled to the passthrough die via a first hybrid bond interconnect; the passthrough die is conductively coupled to a bottom memory die in the stack of memory dies via a second hybrid bond interconnect; and adjacent memory dies in the stack of memory dies are conductively coupled to each other via one or more third hybrid bond interconnects.

Example 13 includes the microelectronic assembly of any of Examples 1-11, wherein: the logic die is conductively coupled to the passthrough die via a first bump interconnect; the passthrough die is conductively coupled to a bottom memory die in the stack of memory dies via a second bump interconnect; and adjacent memory dies in the stack of memory dies are conductively coupled to each other via one or more third bump interconnects.

Example 14 includes the microelectronic assembly of any of Examples 1-13, wherein the logic die comprises a memory controller.

Example 15 includes the microelectronic assembly of any of Examples 1-14, wherein the respective memory dies comprise dynamic random access memory.

Example 16 includes the microelectronic assembly of any of Examples 1-15, further comprising a high-bandwidth memory (HBM), wherein the HBM comprises the logic die, the passthrough die, and the stack of memory dies.

Example 17 includes a microelectronic assembly, comprising: a logic die; and a plurality of memory dies stacked vertically above the logic die, wherein thicknesses of the memory dies are non-uniform, and wherein the thicknesses are based on power required by the respective memory dies.

Example 18 includes the microelectronic assembly of Example 17, wherein a memory die that requires a most power of the plurality of memory dies is thicker than other memory dies of the plurality of memory dies.

Example 19 includes the microelectronic assembly of any of Examples 17-18, wherein a bottom memory die of the plurality of memory dies is thicker than other memory dies of the plurality of memory dies.

Example 20 includes the microelectronic assembly of any of Examples 17-19, wherein: the logic die is conductively coupled to a bottom memory die of the plurality of memory dies via a first hybrid bond interconnect; and adjacent memory dies of the plurality of memory dies are conductively coupled to each other via one or more second hybrid bond interconnects.

Example 21 includes the microelectronic assembly of any of Examples 17-19, wherein: the logic die is conductively coupled to a bottom memory die of the plurality of memory dies via a first bump interconnect; and adjacent memory dies of the plurality of memory dies are conductively coupled to each other via one or more second bump interconnects.

Example 22 includes the microelectronic assembly of any of Examples 17-21, wherein the logic die comprises a memory controller.

Example 23 includes the microelectronic assembly of any of Examples 17-22, wherein the respective memory dies comprise dynamic random access memory.

Example 24 includes the microelectronic assembly of any of Examples 17-23, further comprising a high-bandwidth memory (HBM), wherein the HBM comprises the logic die and the plurality of memory dies.

Example 25 includes an electronic device, comprising: a substrate; a memory conductively coupled to the substrate, wherein the memory comprises: a memory logic die; a plurality of memory dies stacked vertically above the memory logic die; and a passthrough die between the memory logic die and the plurality of memory dies, wherein the memory logic die is conductively coupled to the plurality of memory dies through the passthrough die; and a processor conductively coupled to the substrate, wherein the processor is conductively coupled to the memory through the substrate.

Example 26 includes the electronic device of Example 25, wherein: the substrate is an interposer; and the electronic device further comprises a package substrate, wherein the interposer is conductively coupled to the package substrate.

Example 27 includes the electronic device of any of Examples 25-26, wherein the memory is a high-bandwidth memory, and wherein the respective memory dies comprise dynamic random access memory.

Example 28 includes the electronic device of any of Examples 25-27, wherein the processor is a central processing unit, a graphics processing unit, a vision processing unit, a neural processing unit, or a field-programmable gate array.

Example 29 includes the electronic device of any of Examples 25-28, wherein the memory logic die comprises a memory controller.

Example 30 includes the electronic device of any of Examples 25-29, wherein the memory and the processor have substantially a same thickness.

Example 31 includes the electronic device of any of Examples 25-30, wherein the passthrough die is thicker than at least some of the respective memory dies.

Example 32 includes the electronic device of any of Examples 25-31, wherein the passthrough die comprises a second substrate and one or more vias, wherein the one or more vias extend through the second substrate.

1. A microelectronic assembly, comprising:
a logic die;
a stack of memory dies above the logic die, wherein the stack of memory dies comprises a plurality of memory dies stacked vertically; and
a passthrough die between the logic die and the stack of memory dies, wherein the logic die is conductively coupled to the stack of memory dies through the passthrough die.

2. The microelectronic assembly of claim 1, wherein the passthrough die is thicker than at least some of the respective memory dies.

3. The microelectronic assembly of claim 1, wherein:
the respective memory dies have substantially a same thickness; and
the passthrough die is thicker than the respective memory dies.

4. The microelectronic assembly of claim 1, wherein:
a top memory die in the stack of memory dies is thicker than other memory dies in the stack of memory dies, wherein the top memory die does not comprise through-silicon vias; and
the passthrough die is thicker than at least the other memory dies in the stack of memory dies.

5. The microelectronic assembly of claim 1, wherein the passthrough die comprises a substrate and one or more vias, wherein the one or more vias extend through the substrate.

6. The microelectronic assembly of claim 5, wherein the substrate comprises (i) silicon, (ii) diamond, or (iii) boron and nitrogen.

7. The microelectronic assembly of claim 5, wherein the passthrough die further comprises one or more conductive traces.

8. The microelectronic assembly of claim 5, wherein the passthrough die further comprises active circuitry.

9. The microelectronic assembly of claim 1, wherein:
the logic die is conductively coupled to the passthrough die via a first hybrid bond interconnect;
the passthrough die is conductively coupled to a bottom memory die in the stack of memory dies via a second hybrid bond interconnect; and
adjacent memory dies in the stack of memory dies are conductively coupled to each other via one or more third hybrid bond interconnects.

10. The microelectronic assembly of claim 1, wherein the logic die comprises a memory controller.

11. The microelectronic assembly of claim 1, further comprising a high-bandwidth memory (HBM), wherein the HBM comprises the logic die, the passthrough die, and the stack of memory dies.

12. A microelectronic assembly, comprising:
a logic die; and
a plurality of memory dies stacked vertically above the logic die, wherein thicknesses of the memory dies are non-uniform, and wherein the thicknesses are based on power required by the respective memory dies.

13. The microelectronic assembly of claim 12, wherein a memory die that requires a most power of the plurality of memory dies is thicker than other memory dies of the plurality of memory dies.

14. The microelectronic assembly of claim 12, wherein a bottom memory die of the plurality of memory dies is thicker than other memory dies of the plurality of memory dies.

15. An electronic device, comprising:
a substrate;
a memory conductively coupled to the substrate, wherein the memory comprises:
a memory logic die;
a plurality of memory dies stacked vertically above the memory logic die; and
a passthrough die between the memory logic die and the plurality of memory dies, wherein the memory logic die is conductively coupled to the plurality of memory dies through the passthrough die; and
a processor conductively coupled to the substrate, wherein the processor is conductively coupled to the memory through the substrate.

16. The electronic device of claim 15, wherein:
the substrate is an interposer; and
the electronic device further comprises a package substrate, wherein the interposer is conductively coupled to the package substrate.

17. The electronic device of claim 15, wherein the memory is a high-bandwidth memory, and wherein the respective memory dies comprise dynamic random access memory.

18. The electronic device of claim 15, wherein the processor is a central processing unit, a graphics processing unit, a vision processing unit, a neural processing unit, or a field-programmable gate array.

19. The electronic device of claim 15, wherein the memory and the processor have substantially a same thickness.

20. The electronic device of claim 15, wherein the passthrough die is thicker than at least some of the respective memory dies.
